(19) United States
(12) Patent Application Publication
(10) Pub. No.: US 2026/0262441 A1
(43) Pub. Date: Sep. 3, 2026

(54) METHOD OF STABILIZING PEROVSKITE SINGLE CRYSTAL

(71) Applicant: EWHA UNIVERSITY-INDUSTRY COLLABORATION FOUNDATION, Seoul (KR)

(72) Inventors: William JO, Seoul (KR); Jihyun KIM, Seoul (KR); Geumha LIM, Seoul (KR)

(21) Appl. No.: 19/550,355

(22) Filed: Feb. 26, 2026

(30) Foreign Application Priority Data
Feb. 28, 2025 (KR) 10-2025-0026399
Dec. 5, 2025 (KR) 10-2025-0191017

(51) Int. Cl. H10K 85/50; C07F 7/24; C30B 7/06

(52) U.S. Cl. CPC H10K 85/50; C07F 7/24; C30B 7/06

(57) ABSTRACT

The present disclosure relates to a method of stabilizing a perovskite single crystal, and to a perovskite thin film and an optoelectronic device prepared using the same. According to embodiments of the present disclosure, a method of stabilizing a perovskite single crystal enables the alpha phase of the single crystal present immediately after preparation to be maintained, as compared with conventional methods in which a prepared single crystal is sealed and stored. Further, while the alpha phase of the single crystals present immediately after fabrication is maintained, the peak intensity for (100) crystal plane may be enhanced, thereby improving crystallinity. Such stabilized perovskite single crystals may be used to prepare a high-purity precursor solution. When a thin film is prepared using the precursor solution, defects generated during thin-film preparation processes can be reduced. Accordingly, the prepared perovskite thin film may exhibit a low trap density and excellent long-term stability.

### CROSS-REFERENCE TO RELATED APPLICATIONS

This application claims the benefit under 35 U.S.C. 119(α) of Korean Patent Applications No. 10-2025-0026399 filed on Feb. 28, 2025, and No. 10-2025-0191017 filed on Dec. 5, 2025, in the Korean Intellectual Property Office, the entire disclosures of which are incorporated herein by reference for all purposes.

### TECHNICAL FIELD

The present disclosure relates to a method of stabilizing a perovskite single crystal, and to a perovskite thin film and an optoelectronic device prepared using the same.

### BACKGROUND

Perovskite solar cells have emerged as a significant photovoltaic technology due to their high power conversion efficiency and low-cost preparation potential. In particular, certified power conversion efficiencies (PCEs) of perovskite solar cells have improved from 3.8% to 26%, thereby making perovskite solar cells competitive with conventional silicon-based solar cells. However, commercialization of perovskite solar cells remains limited by chemical and structural instability of halide perovskite materials.

Most previously reported perovskite devices are prepared based on polycrystalline thin films and their performance is limited by high trap densities and degraded stability attributed to grain boundaries. In contrast, perovskite single crystals have been reported to exhibit superior properties, including extended carrier diffusion lengths, reduced trap densities, and enhanced stability, as compared to polycrystalline thin films. Accordingly, perovskite single crystals have been proposed for use in various fields, such as solar cells, photodetectors, light emitting diodes, and lasers.

However, halide perovskites are vulnerable to oxygen and moisture, which can readily disrupt their crystal structures. Further, defects generated during thin-film preparation processes may further degrade the phase stability of perovskites. Accordingly, efforts have been made to employ high-purity perovskite single crystals as precursor sources in order to suppress defect formation originating from impure or structurally unstable starting materials.

### PRIOR ART DOCUMENT

### Patent Literature

Korean Patent Registration No. 2518158

### SUMMARY

The present disclosure addresses the instability of perovskite single crystals during storage and subsequent thin-film formation processes, and provides a storage-based stabilization method capable of preserving the α-phase crystallographic structure while enhancing crystallinity.

However, problems to be solved by the present disclosure are not limited to the above-described problems, and although not described herein, other problems to be solved by the present disclosure can be clearly understood by those skilled in the art from the following descriptions.

A first aspect of the present disclosure provides a method of stabilizing a perovskite single crystal, including: synthesizing a perovskite single crystal; and stabilizing the perovskite single crystal by storing the perovskite single crystal at room temperature under a relative humidity of about 10% or less for about 3 days to about 90 days.

A second aspect of the present disclosure provides a method of preparing a perovskite optoelectronic device, including: preparing a stabilized perovskite single crystal by the method according to the first aspect; preparing a precursor solution using the stabilized perovskite single crystal; and preparing a perovskite thin film using the precursor solution.

A third aspect of the present disclosure provides a perovskite optoelectronic device prepared by the method according to the second aspect.

According to embodiments of the present disclosure, a method of stabilizing a perovskite single crystal enables the alpha phase of the single crystal present immediately after preparation to be maintained, as compared with conventional methods in which a prepared single crystal is sealed and stored. Further, while the alpha phase of the single crystals present immediately after fabrication is maintained, the peak intensity for (100) crystal plane may be enhanced, thereby improving crystallinity. Such stabilized perovskite single crystals may be used to prepare a high-purity precursor solution. When a thin film is prepared using the precursor solution, defects generated during thin-film preparation processes can be reduced. Accordingly, the prepared perovskite thin film exhibits reduced trap density and improved long-term operational stability, as evidenced by XRD, TRPL, and device performance evaluations.

### BRIEF DESCRIPTION OF THE DRAWINGS

FIGS. 1A and 1B show X-ray diffraction (XRD) patterns of perovskite thin films (D1, D2, and D3) according to an example of the present disclosure.

FIGS. 2A to 2D show X-ray Photoelectron Spectroscopy (XPS) measurement results of the perovskite thin films (D1, D2, and D3) according to an example of the present disclosure.

FIGS. 3A to 3C show space charge limited current (SCLC) measurement results of the perovskite thin films (D1, D2, and D3) according to an example of the present disclosure.

FIGS. 4A and 4B(i) to 4B(iii) show surface photovoltage (SPV) measurement results of the perovskite thin films (D1, D2, and D3) according to an example of the present disclosure.

FIGS. 5A to 5D show photoluminescence (PL) and time-resolved PL (TRPL) analysis results of the perovskite thin films (D1, D2, and D3) according to an example of the present disclosure.

FIGS. 6A to 6C show efficiency measurement results of a perovskite optoelectronic device according to an example of the present disclosure.

FIG. 7 shows long-term stability measurement results of the perovskite optoelectronic device according to an example of the present disclosure.

FIGS. 8A(i), 8A(ii), 8B(i) and 8B(ii) show Transmission Electron Microscopy (TEM) measurement results of a perovskite single crystal according to an example of the present disclosure.

### DETAILED DESCRIPTION

Hereinafter, embodiments and examples of the present disclosure will be described in detail with reference to the accompanying drawings so that the present disclosure may be readily implemented by those skilled in the art. However, it is to be noted that the present disclosure is not limited to the embodiments and examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl” or “alkyl group” may individually include linear or branched alkyl groups having 1 to 12 carbon atoms, 1 to 10 carbon atoms, 1 to 8 carbon atoms, or 1 to 5 carbon atoms, and all the possible isomers thereof. For example, the alkyl or alkyl group may individually include methyl group (Me), ethyl group (Et), n-propyl group (nPr), iso-propyl group (iPr), n-butyl group (nBu), iso-butyl group (iBu), tert-butyl group (tBu), sec-butyl group (sBu), n-pentyl group (nPe), iso-pentyl group (iPe), sec-pentyl group (sPe), tert-pentyl group (tPe), n-hexyl group, iso-hexyl group, heptyl group, 4,4-dimethyl pentyl group, octyl group, 2,2,4-trimethyl pentyl group, nonyl group, decyl group, undecyl group, dodecyl group, and isomers thereof, but may not be limited thereto.

In the following description, exemplary embodiments of the present disclosure will be described in detail, but the present disclosure may not be limited thereto.

A first aspect of the present disclosure provides a method of stabilizing a perovskite single crystal, including: synthesizing a perovskite single crystal; and stabilizing the perovskite single crystal by storing the perovskite single crystal at room temperature under a relative humidity of about 10% or less for about 3 days to about 90 days.

According to an embodiment of the present disclosure, the method may include stabilizing the perovskite single crystal by storing the perovskite single crystal at room temperature under a relative humidity of about 10% or less, or about 1% to about 10%, for about 3 days to about 90 days, about 3 days to about 80 days, about 3 days to about 70 days, about 3 days to about 60 days, about 3 days to about 55 days, about 3 days to about 50 days, about 3 days to about 45 days, about 5 days to about 90 days, about 5 days to about 80 days, about 5 days to about 70 days, about 5 days to about 60 days, about 5 days to about 55 days, about 5 days to about 50 days, about 5 days to about 45 days, about 7 days to about 90 days, about 7 days to about 80 days, about 7 days to about 70 days, about 7 days to about 60 days, about 7 days to about 55 days, about 7 days to about 50 days, or about 7 days to about 45 days, but may not be limited thereto.

According to an embodiment of the present disclosure, the room temperature may be within a range of about 18° C. to about 30° C.

According to an embodiment of the present disclosure, the perovskite single crystal may include a compound represented by the following Chemical Formula 1:

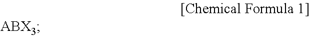

in Chemical Formula 1,

A is an organic cation selected from the group consisting of CH₃NH₃⁺, CH₃CH₂NH₃⁺, and HC(═NH)NH₂⁺, or an inorganic cation selected from the group consisting of Cs⁺ and Rb⁺;
B is a metal cation selected from the group consisting of Pb²⁺, Sn²⁺, Cu²⁺, Ni²⁺, Co²⁺, Fe²⁺, Mn²⁺, Cr²⁺, Pd²⁺, Cd²⁺, Yb²⁺, Ge²⁺, and Eu²⁺; and

X independently represents Cl⁻, Br⁻, or I⁻.

According to an embodiment of the present disclosure, the stabilized perovskite single crystal may include an alpha (α)-phase perovskite single crystal.

According to an embodiment of the present disclosure, the stabilized perovskite single crystal may maintain an alpha phase that is present immediately after preparation of the perovskite single crystal.

According to an embodiment of the present disclosure, the stabilized perovskite single crystal may exhibit an increased X-ray diffraction (XRD) peak intensity for (100) crystal plane, as compared to before stabilization.

A second aspect of the present disclosure provides a method of preparing a perovskite optoelectronic device, including: preparing a stabilized perovskite single crystalby the method according to the first aspect; preparing a precursor solution using the stabilized perovskite single crystal; and preparing a perovskite thin film using the precursor solution.

Detailed descriptions of parts of the second aspect, which overlap with those of the first aspect, are omitted hereinafter, but the descriptions of the first aspect of the present disclosure may be identically applied to the second aspect of the present disclosure, even though they are omitted hereinafter.

According to an embodiment of the present disclosure, the method may further include passivating the perovskite thin film.

According to an embodiment of the present disclosure, the perovskite thin film may exhibit reduced defects, a low trap density, and excellent long-term stability, as compared to a thin film prepared from vacuum-sealed or a non-stabilized perovskite single crystal. Accordingly, by maintaining a low trap density over an extended period, long charge lifetimes may be preserved.

A third aspect of the present disclosure provides a perovskite optoelectronic device prepared by the method according to the second aspect.

Detailed descriptions of parts of the third aspect, which overlap with those of the first aspect and the second aspect, are omitted hereinafter, but the descriptions of the first aspect and the second aspect of the present disclosure may be identically applied to the third aspect of the present disclosure, even though they are omitted hereinafter.

According to an embodiment of the present disclosure, the perovskite optoelectronic device may have a structure in which a substrate, a first electrode (transparent electrode), an electron transport layer, a perovskite thin film, a hole transport layer, and a second electrode are sequentially stacked.

According to an embodiment of the present disclosure, the perovskite optoelectronic device may further include a passivation layer on the perovskite thin film.

According to an embodiment of the present disclosure, the substrate, the first electrode, the electron transport layer, the hole transport layer, and the second electrode may each be formed of materials commonly used in optoelectronic devices, without limitation. For example, the substrate may include, without limitation, glass or a transparent polymer. The first electrode, as a transparent electrode, may include, without limitation, indium tin oxide (ITO), indium zinc oxide (IZO), gallium zinc oxide (GZO), aluminum zinc oxide (AZO), aluminum gallium zinc oxide (AGZO), indium gallium zinc oxide (IGZO), or fluorine-doped tin oxide (FTO). The electron transport layer may include, without limitation, SnO₂, TiO₂, ZnO, WO₃, or RuO₂. The hole transport layer may include, without limitation, Spiro-OMeTAD.

Hereinafter, the present disclosure will be described in more detail with reference to Examples, but the present disclosure may not be limited thereto.

### EXAMPLE

### 1. Preparation of Perovskite Optoelectronic Device

### 1) Preparation of Electron Transport Layer

An SnO₂ nanoparticle solution and deionized water (DI water) were mixed at a volume ratio of 1:4 to prepare an SnO₂ solution. A pre-cleaned glass/ITO transparent electrode was treated with UV ozone for 20 minutes, followed by spin coating 150 μL of the SnO₂ solution at 4000 rpm for 30 seconds. Thereafter, the coated electrode was heat-treated on a hot plate at 150° C. for 30 minutes.

### 2) Synthesis of Formamidinium Iodide (FAI)

A formamidinium acetate powder (15 g) was placed in a round-bottom flask and allowed to react slowly with a hydroiodic acid solution for 30 minutes in an ice bath. The reaction solution was treated using a rotary evaporator under reduced pressure for 2 hours to remove the solvent, thereby obtaining a yellow powder. The obtained powder was washed with an ether solution for 3 to 4 hours to obtain a white formamidinium iodide (FAI) powder. The FAI powder was dissolved in an ethanol solution, and ether was slowly added dropwise to perform recrystallization twice, thereby improving purity. The final powder was washed with an ether solution and dried in a vacuum desiccator for 24 hours.

### 3) Synthesis of Perovskite FAPbl₃ Single Crystal

The FAI powder and Pbl₂ powder were dissolved in a γ-butyrolactone (GBL) solution for at least 24 hours. The solution was filtered using a 0.2 μm hydrophilic filter and transferred to a round-bottom flask, followed by an oil bath process. The oil bath was heated from 80° C. to 120° C. in 10° C. increments for 4 hours. The grown black α-FAPbl₃ single crystals were sequentially washed with an acetonitrile solution and an ether solution. The washed single crystals were dried on a hot plate at 150° C. for 30 minutes.

### 4) Storage of FAPbl₃ Single Crystal

The dried α-FAPbl₃ single crystals were stored under the following three conditions prior to preparation of precursor solutions. The single crystals were used immediately after synthesis to prepare a precursor solution (fresh α-FAPbl₃). The single crystals were placed in a transparent vial, sealed, and stored in a desiccator at room temperature under a relative humidity of less than 10%. Then, the single crystals underwent a phase transition to a yellow delta (6) phase, followed by preparation of a precursor solution (sealed δ-FAPbl₃). In this case, the phase transition occurred within 3 days. The single crystals were placed in a vial and stored in a desiccator at room temperature under a relative humidity of less than 10% to maintain a black alpha (α) phase, and were subsequently used to prepare a precursor solution (open α-FAPbl₃).

### 5) Preparation and Passivation of Perovskite Thin Film

FAPbl₃ single crystals and 30 mol % methylammonium chloride (MACI) powder were dissolved in a mixed solvent of N,N-dimethylformamide (DMF) and dimethyl sulfoxide (DMSO) at a volume ratio of 4:1 to prepare a precursor solution having a concentration of 1.6 M. Precursor solutions D1, D2, and D3 were prepared using fresh α-FAPbl₃, sealed δ-FAPbl₃ stored for 45 days after synthesis, and open α-FAPbl₃ stored for 45 days after synthesis, respectively.

The precursor solution (50 μL) was deposited on the electron transport layer thin film and spin-coated at 4000 rpm for 25 seconds (acceleration: 800 rpm-s⁻¹). Ten seconds before completion of spin coating, 870 μL of an ether solution was applied to remove the solvent. The coated perovskite thin film was heat-treated on a hot plate at 100° C. for 10 minutes and at 150° C. for 10 minutes. An octylammonium iodide (OAI) powder was dissolved in an isopropyl alcohol (IPA) solution to prepare an OA solution, which was applied onto a surface of the perovskite thin film and spin-coated at 3000 rpm for 30 seconds to perform surface passivation.

### 6) Device Preparation

A hole transport layer (Spiro-MeOTAD) was spin-coated onto the passivated perovskite thin film, followed by deposition of gold as a second electrode using a thermal evaporator.

### Test Example

### 1. X-Ray Diffraction (XRD)

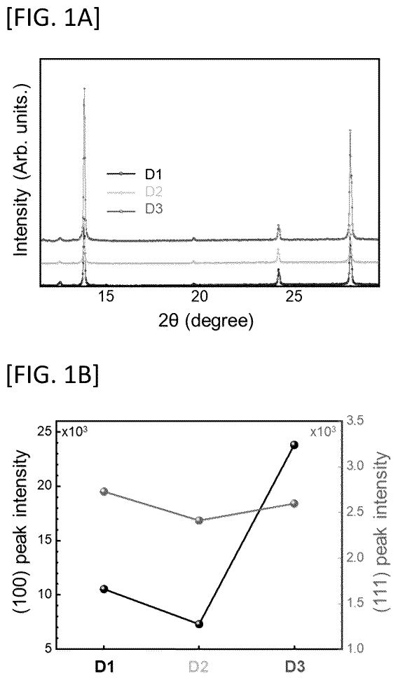

After preparation of the perovskite thin films of D1, D2, and D3, X-ray diffraction (XRD) patterns were measured. Referring to FIG. 1A and FIG. 1B, it was confirmed that crystallinity in a (100) orientation of D3 was significantly improved as compared to D1 and D2. The D2 thin film stored in a sealed environment exhibited lower crystallinity in all crystallographic orientations than the D1 and D3 thin films.

### 2. X-Ray Photoelectron Spectroscopy (XPS)

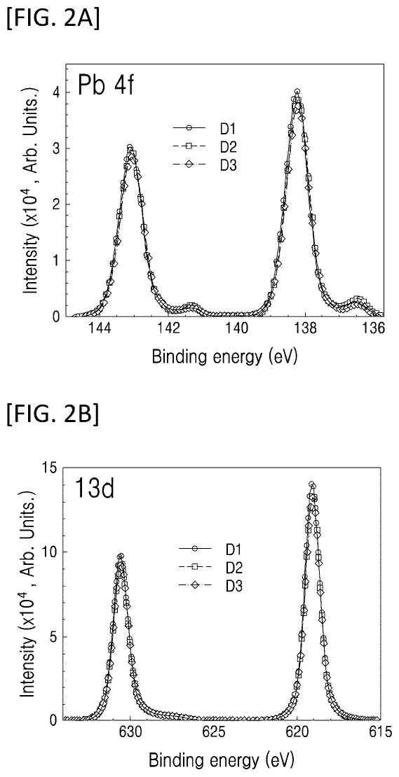

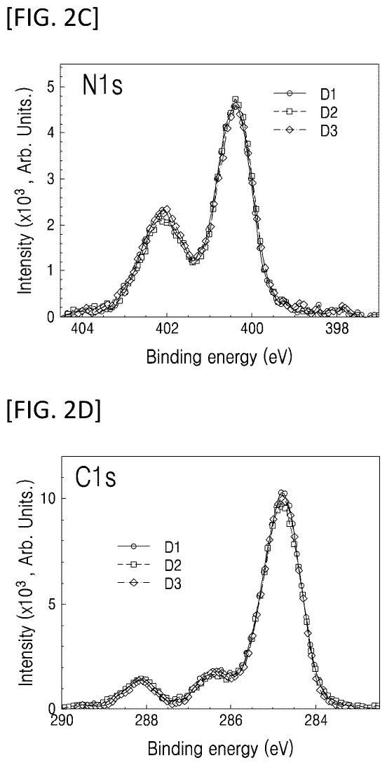

Referring to FIG. 2A to FIG. 2D, it was observed that element-specific XPS spectra of the perovskites in D1, D2, and D3 were similar. This indicates that no significant chemical composition changes occurred with respect to the storage method or duration of the single crystals.

### 3. Space Charge Limited Current (SCLC)

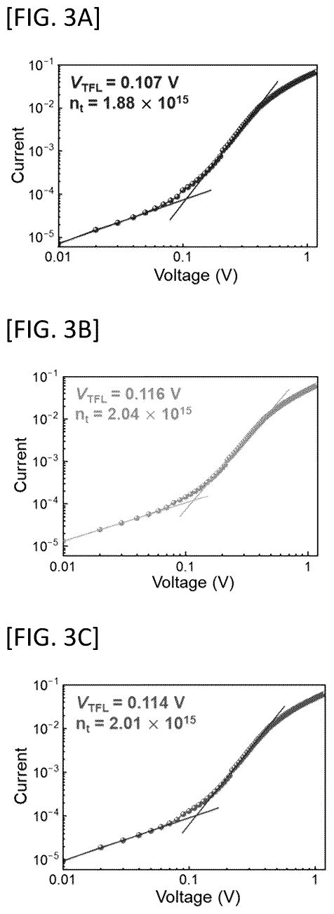

FIG. 3A to FIG. 3C show SCLC measurement results of the D1, D2, and D3 thin films, respectively. Based on charge trap density measurements and calculations, D1 exhibited the lowest trap density, whereas D2 exhibited the highest trap density.

### 4. Surface Photovoltage (SPV)

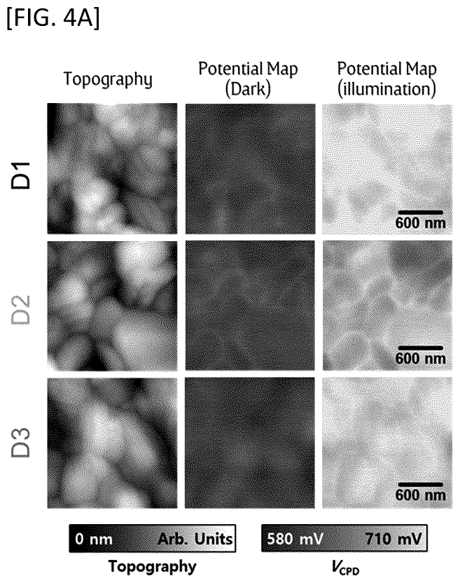

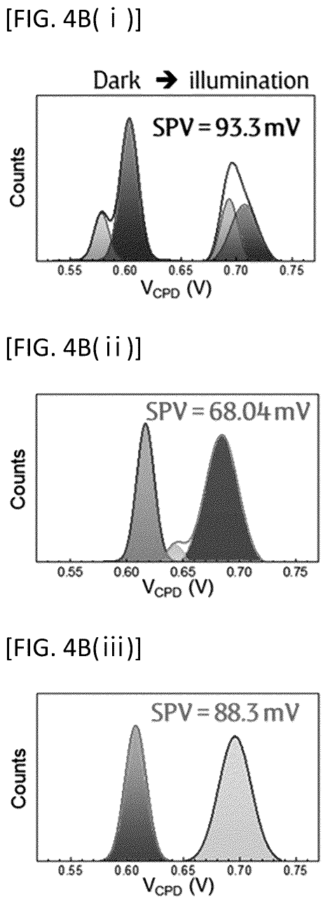

FIG. 4A and FIGS. 4B(i) to 4B(iii) show SPV measurement results of D1, D2, and D3. D1 exhibited the lowest photocarrier recombination rate due to its low trap density, whereas D2 exhibited the highest photocarrier recombination rate.

### 5. Photoluminescence (PL) and Time-Resolved Photoluminescence (TRPL) Analysis

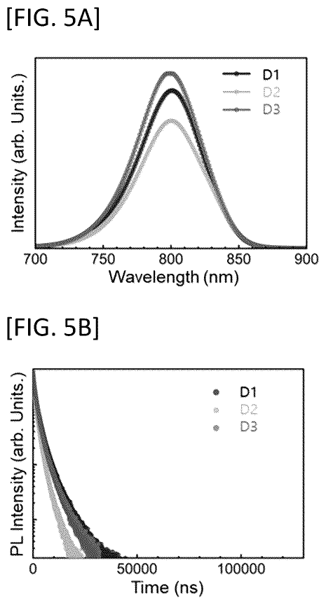

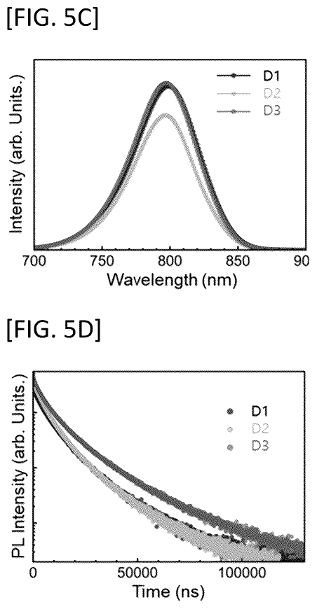

FIG. 5A and FIG. 5B show PL and TRPL measurement results of D1, D2, and D3 immediately after preparation(as-prepared). FIG. 5C and FIG. 5D show PL and TRPL measurement results one month after preparation. Specific values of TRPL fitting data are summarized in Table 1 below. Referring to FIG. 5A to FIG. 5D and Table 1, the D1 thin film exhibited the longest charge lifetime immediately after preparation, whereas the D3 thin film exhibited the longest charge lifetime after one month. This confirms that the D3 perovskite thin film maintains a low trap density over an extended period.

TABLE 1

| | | A₁(%) | A₂(%) | T₁(μs) | T₂(μs) | τₐᵥₑ(μs) |
|---|---|---|---|---|---|---|
| As- | D1 | 28.72 | 16.85 | 0.91 | 3.14 | 2.40 |
| prepared | D2 | 29.03 | 17.27 | 0.67 | 1.99 | 1.51 |
| | D3 | 30.19 | 16.57 | 0.85 | 2.81 | 2.12 |
| One month | D1 | 15.94 | 22.32 | 0.83 | 6.17 | 5.67 |
| after | D2 | 19.38 | 22.48 | 1.86 | 8.24 | 7.20 |
| preparation | D3 | 21.60 | 21.71 | 2.55 | 11.58 | 9.96 |

### 6. Device Efficiency Evaluation

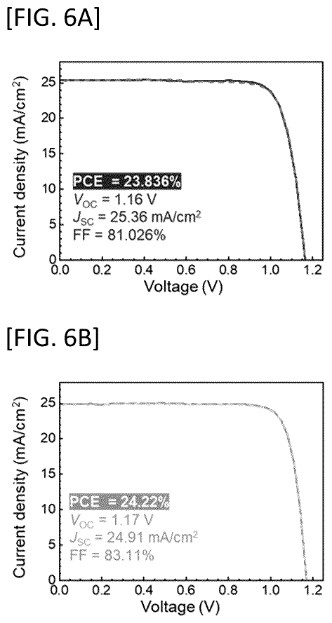

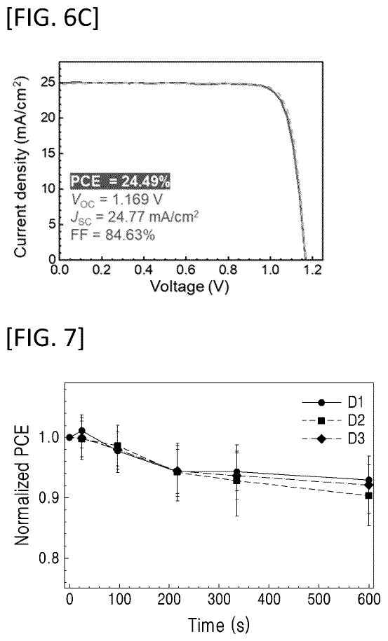

FIG. 6A to FIG. 6C show efficiency measurement results of D1, D2, and D3 devices, respectively. Each device was prepared using FAPbl₃ single crystals stored for 45 days under the respective storage conditions. The highest efficiency was obtained from the D3 device. FIG. 7 shows long-term stability evaluation results. D3 maintained stability comparable to D1, whereas D2 exhibited slightly reduced stability.

### 7. Transmission Electron Microscopy (TEM)

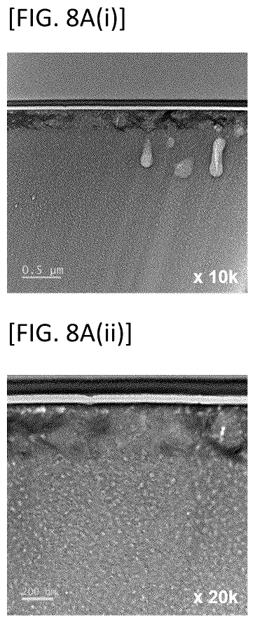

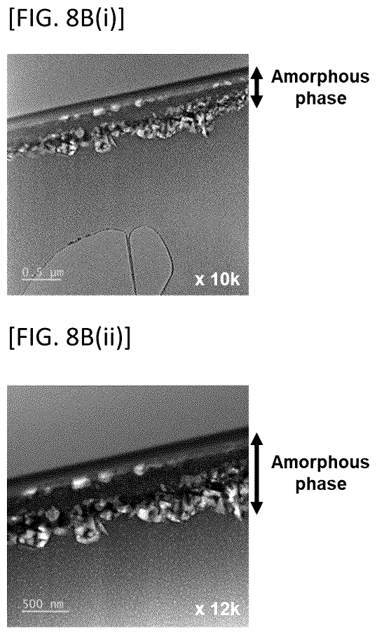

TEM analysis was performed on fresh α-FAPbl₃ single crystals and α-FAPbl₃ single crystals stored for one year under open conditions to investigate phase changes of the single crystals. The α-phase was observed throughout the fresh α-FAPbl₃ single crystals from the surface to the bulk (FIGS. 8A(i) and 8A(ii)). In the α-FAPbl₃ single crystals stored for one year under open conditions, the surface transitioned to an amorphous phase, whereas the bulk maintained the α-phase (FIGS. 8B(i) and 8B(ii)).

The above description of the present disclosure is provided for the purpose of illustration, and it would be understood by those skilled in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the example. It shall be understood that all modifications and examples conceived from the meaning and scope of the claims and their equivalents are included in the scope of the present disclosure.

We claim:

1. A method of stabilizing a perovskite single crystal, comprising:
synthesizing a perovskite single crystal; and
stabilizing the perovskite single crystal by storing the perovskite single crystal at room temperature under a relative humidity of 10% or less for 3 days to 90 days.

2. The method of claim 1,
wherein the method includes stabilizing the perovskite single crystal by storing the perovskite single crystal at room temperature under a relative humidity of 10% or less for 7 days to 45 days.

3. The method of claim 1,
wherein the perovskite single crystal includes a compound represented by the following Chemical Formula 1: 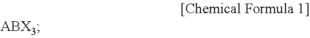
in Chemical Formula 1,
A is an organic cation selected from the group consisting of CH₃NH₃⁺, CH₃CH₂NH₃⁺, and HC(═NH)NH₂⁺,
or an inorganic cation selected from the group consisting of Cs⁺ and Rb⁺;
B is a metal cation selected from the group consisting of Pb²⁺, Sn²⁺, Cu²⁺, Ni²⁺, Co²⁺, Fe²⁺, Mn²⁺, Cr²⁺,
Pd²⁺, Cd²⁺, Yb²⁺, Ge²⁺, and Eu²⁺; and
X independently represents Cl⁻, Br⁻, or I⁻.

4. The method of claim 1,
wherein the stabilized perovskite single crystal includes an alpha(α)-phase perovskite single crystal.

5. The method of claim 1,
wherein the stabilized perovskite single crystal exhibits an increased X-ray diffraction (XRD) peak intensity for (100) crystal plane, as compared to before stabilization.

6. A method of preparing a perovskite optoelectronic device, comprising:
preparing a stabilized perovskite single crystal by the method according to claim 1;
preparing a precursor solution using the stabilized perovskite single crystal; and
preparing a perovskite thin film using the precursor solution.

7. The method of claim 6, further comprising:
passivating the perovskite thin film.

8. A perovskite optoelectronic device prepared by the method according to claim 6.
